(19) United States
(12) Patent Application Publication
(10) Pub. No.: US 2013/0341750 A1
(43) Pub. Date: Dec. 26, 2013

(54) SOLID-STATE IMAGING DEVICE, METHOD FOR CONTROLLING THE SAME, AND ELECTRONIC APPARATUS

(71) Applicant: Sony Corporation, Tokyo (JP)

(72) Inventors: Tatsuya Ichikawa, Kanagawa (JP); Hayato Wakabayashi, Tokyo (JP); Hisashi Kurebayashi, Kanagawa (JP)

(21) Appl. No.: 13/918,242

(22) Filed: Jun. 14, 2013

(30) Foreign Application Priority Data
Jun. 25, 2012 (JP) 2012-141670

(51) Int. Cl. H01L 27/146

(52) U.S. Cl. CPC H01L 27/14605
USPC 257/440

(57) ABSTRACT

There is provided a solid-state imaging device including a plurality of pixels which are arranged in a two-dimensional array form and in each of which color separation is performed in a substrate depth direction. The solid-state imaging device includes a pixel addition section which performs addition, when pixel signals of the plurality of pixels are added up to be outputted, by setting addition regions of pixel signals of a first color component to be shifted from addition regions of pixel signals of a second color component at regular intervals.

### BACKGROUND

The present technology relates to a solid-state imaging device, a method for controlling the same, and an electronic apparatus, and particularly relates to a solid-state imaging device, a method for controlling the same, and an electronic apparatus which make it possible to enhance output resolution in the solid-state imaging device performing color separation in a substrate depth direction.

There is a solid-state imaging device in which color filters of respective colors are arranged in respective pixels, like a Bayer array or the like, and a plurality of colors (R, G, and B, in general) as a whole are read out from the pixels adjacent to one another. In recent years, there is also proposed a solid-state imaging device which includes pixels each having photoelectric conversion portions for a respective plurality of colors, the photoelectric conversion portions being arranged in a substrate depth direction. Thus, the solid-state imaging device is capable of reading out the plurality of colors from each pixel (see JP 2009-516914A, for example). According to the solid-state imaging device performing the color separation in the depth direction, light can be efficiently used, and thus pixel characteristic enhancement is expected. In addition, an abundance of color information can be used, and thus image quality enhancement after color processing is expected.

For the solid-state imaging device performing the color separation in the substrate depth direction, there is proposed a structure in which, to enhance the output resolution, a pixel array of a first layer serving as one light receiving portion and a pixel array of at least one layer serving as the other light receiving portion are arranged in such a manner that the pixel array of the other light receiving portion is shifted from the pixel array of the one light receiving portion (see JP 2009-54806A, for example).

### SUMMARY

However, in the technique in JP 2009-54806A, it is necessary to set the size of microlenses to be half of the pixel pitch, and is it not possible to efficiently handle light in comparison with a general case where microlenses are arranged for respective pixels. There is a concern that sensitivity might be lowered.

The present technology is provided in view of such circumstances and makes it possible to enhance output resolution in a solid-state imaging device performing the color separation in the substrate depth direction.

According to a first embodiment of the present disclosure, there is provided a solid-state imaging device including a plurality of pixels which are arranged in a two-dimensional array form and in each of which color separation is performed in a substrate depth direction, the solid-state imaging device including a pixel addition section which performs addition, when pixel signals of the plurality of pixels are added up to be outputted, by setting addition regions of pixel signals of a first color component to be shifted from addition regions of pixel signals of a second color component at regular intervals.

According to a second embodiment of the present disclosure, there is provided a method for controlling a solid-state imaging device including a plurality of pixels which are arranged in a two-dimensional array form and in each of which color separation is performed in a substrate depth direction, the method being performed by the solid-state imaging device, the method including performing addition, when pixel signals of the plurality of pixels are added up to be outputted, by setting addition regions of pixel signals of a first color component to be shifted from addition regions of pixel signals of a second color component at regular intervals.

According to a third embodiment of the present disclosure, there is an electronic apparatus including a solid-state imaging device including a plurality of pixels which are arranged in a two-dimensional array form and in each of which color separation is performed in a substrate depth direction, the solid-state imaging device including a pixel addition section which performs addition, when pixel signals of the plurality of pixels are added up to be outputted, by setting addition regions of pixel signals of a first color component to be shifted from addition regions of pixel signals of a second color component at regular intervals.

According to the first to third embodiments of the present technology, in the solid-state imaging device including the plurality of pixels which are arranged in the two-dimensional array form and in each of which color separation is performed in a substrate depth direction, addition is performed when pixel signals of the plurality of pixels are added up to be outputted, by setting addition regions of pixel signals of the first color component to be shifted from addition regions of pixel signals of the second color component at regular intervals.

According to the first to third embodiments of the present technology, it is possible to enhance the output resolution in the solid-state imaging device performing the color separation in the substrate depth direction.

### BRIEF DESCRIPTION OF THE DRAWINGS

FIG. 1 is a diagram showing a schematic configuration of a solid-state imaging device to which an embodiment of the present technology is applied;

FIG. 2 is a diagram illustrating a structure of a photoelectric conversion portion in a pixel;

FIG. 3 is a diagram showing a circuit configuration example of the pixel;

FIG. 4 is a diagram illustrating output signals from the pixels in the case where output mode is all-pixel output mode;

FIG. 5 is a diagram illustrating general addition control processing;

FIG. 6 is a diagram illustrating addition control processing by the solid-state imaging device in FIG. 1;

FIG. 7 is a timing chart showing an operation of each pixel in the all-pixel output mode;

FIG. 8 is a timing chart showing an operation of the pixel in thinning mode;

FIG. 9 is a flowchart illustrating pixel-addition/output processing; and

FIG. 10 is a block diagram showing a configuration example of an imaging apparatus serving as an electronic apparatus to which the embodiment of the present technology is applied.

### DETAILED DESCRIPTION OF THE EMBODIMENT

### Schematic Configuration Example of Solid-State Imaging Device

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

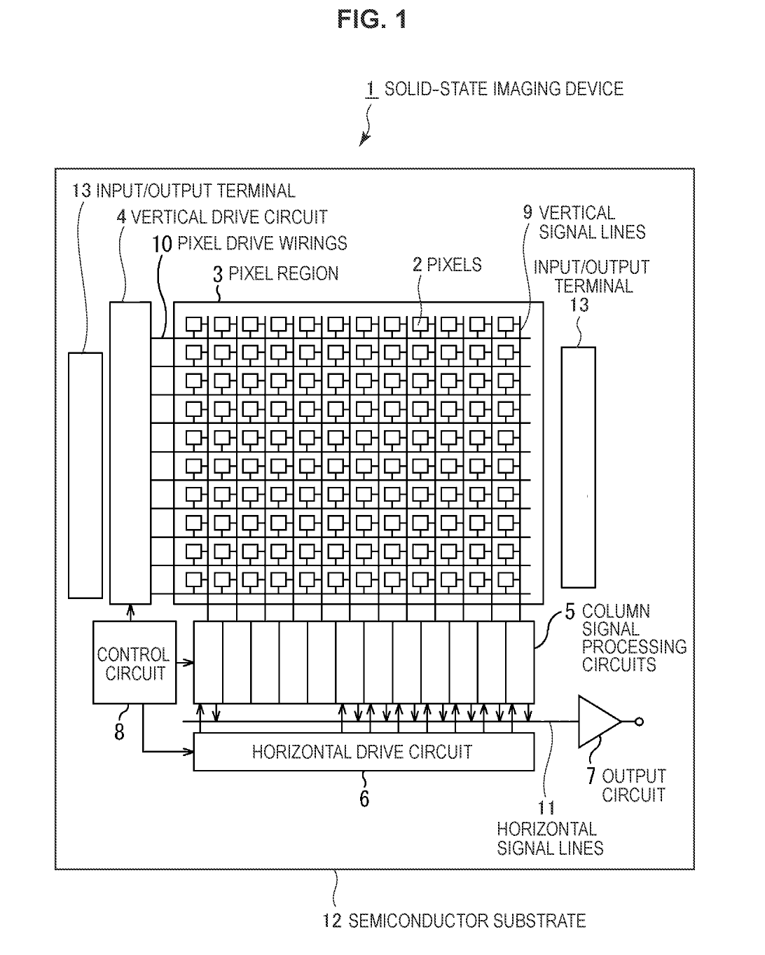

FIG. 1 shows a schematic configuration of a solid-state imaging device to which an embodiment of the present technology is applied. A solid-state imaging device 1 in FIG. 1 is a backside illuminated MOS solid-state imaging device.

The solid-state imaging device 1 in FIG. 1 includes a semiconductor substrate 12 using silicon (Si) as a semiconductor, a pixel region 3 having pixels 2 arranged in a two-dimensional array form over the semiconductor substrate 12, and a peripheral circuit part around the pixel region 3. The peripheral circuit part includes a vertical drive circuit 4, column signal processing circuits 5, a horizontal drive circuit 6, an output circuit 7, a control circuit 8, and the like.

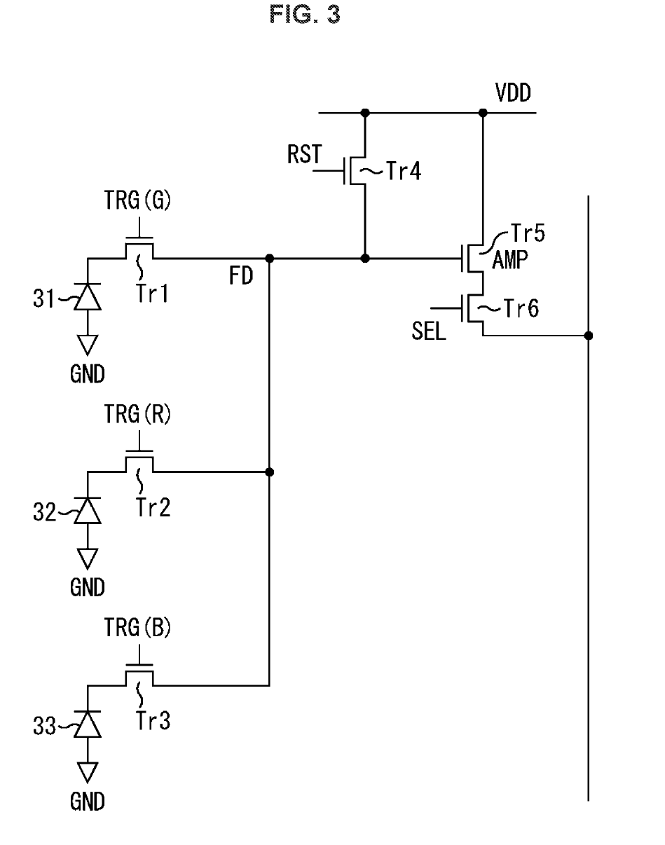

The pixels 2 each include a plurality of photoelectric conversion portions arranged in a stacked manner in a substrate depth direction, and a plurality of pixel transistors (so-called MOS transistors). The plurality of pixel transistors are of four types, for example: a transfer transistor, a selection transistor, a reset transistor, and an amplification transistor, as will be described later with reference to FIG. 3.

In addition, the pixels 2 may have a shared pixel structure. In the shared pixel structure, each pixel includes a plurality of photodiodes, a plurality of transfer transistors, one floating diffusion region that is shared, and the other individual types of the pixel transistors that are shared. In other words, in each shared pixel, the photodiodes and the transfer transistors that form a plurality of unit pixels share the other individual types of the pixel transistors.

The control circuit 8 receives an input clock and data for instruction for operation mode and the like, and outputs data such as internal information of the solid-state imaging device 1. In other words, based on a vertical synchronizing signal, a horizontal synchronizing signal, and a master clock, the control circuit 8 generates a clock signal and a control signal which serve as reference for operations of the vertical drive circuit 4, the column signal processing circuits 5, and the horizontal drive circuit 6. Then, the control circuit 8 inputs the clock signal and the control signal thus generated to the vertical drive circuit 4, the column signal processing circuits 5, the horizontal drive circuit 6, and the like.

The vertical drive circuit 4 includes, for example, a shift register, selects one of pixel drive wirings 10, supplies the selected pixel drive wiring 10 with pulses for driving the pixels. The vertical drive circuit 4 drives the pixels 2 in row unit. In other words, the vertical drive circuit 4 performs selective scanning on the pixels 2 in the pixel region 3 for each row in turn in a vertical direction, and supplies the column signal processing circuits 5, through the vertical signal lines 9, with pixel signals based on signal charges generated in accordance with amounts of received light in photoelectric conversion portions of the pixels 2.

The column signal processing circuits 5 are respectively arranged for columns of the pixels 2, and perform, in column unit, signal processing such as noise removal on signals outputted from the pixels 2 in one row. For example, the column signal processing circuits 5 perform signal processing such as CDS (Correlated Double Sampling) for removing fixed pattern noise intrinsic to the pixels 2, signal amplification, and AD conversion.

The horizontal drive circuit 6 includes a shift register, for example. The horizontal drive circuit 6 serially outputs horizontal scanning pulses to thereby select each of the column signal processing circuits 5 in turn, and causes the column signal processing circuits 5 to output respective pixel signals to the horizontal signal lines 11.

The output circuit 7 performs signal processing on the signals serially supplied from the column signal processing circuits 5 through the horizontal signal lines 11, respectively, and outputs the processed signals. The output circuit 7 performs, for example, only buffering, or performs black level adjustment, column variation correction, various digital signal processing, and the like, depending on the case. Input/output terminals 13 exchange signals with an external apparatus.

### Structure of Photoelectric Conversion Portions

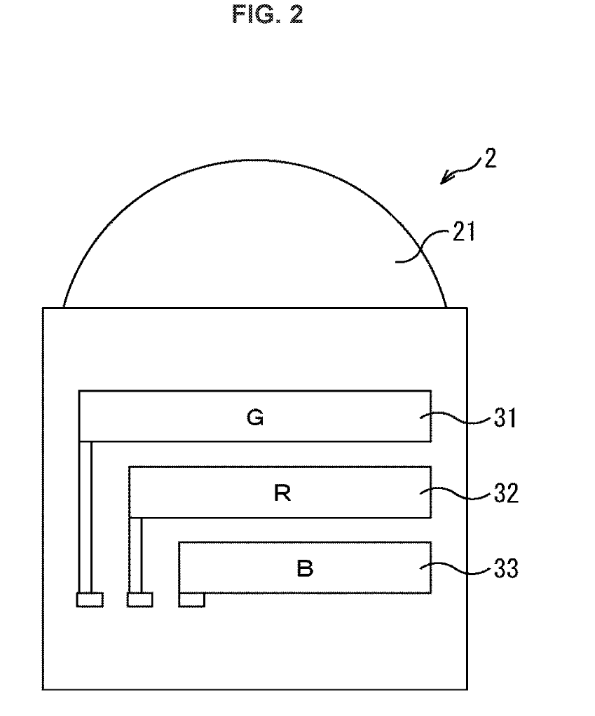

A structure of photoelectric conversion portions of each of the pixels 2 will be described with reference to FIG. 2.

Each pixel 2 has the structure in which a plurality of photoelectric conversion portions arranged in a stacked manner in the substrate depth direction.

As shown in FIG. 2, an on-chip lens 21 is formed on the back-surface side of the semiconductor substrate 12 (not shown in FIG. 2), the back-surface being a light incident surface of the pixel 2. This means that the solid-state imaging device 1 in FIG. 1 includes the one on-chip lens 21 (microlens) provided for each pixel 2.

In the pixel 2, a first photoelectric conversion portion 31 which photoelectrically converts first color light, a second photoelectric conversion portion 32 which photoelectrically converts second color light, and a third photoelectric conversion portion 33 which photoelectrically converts third color light are formed in this order in the substrate depth direction from the on-chip lens 21. In the present embodiment, the first color is green (GR); the second color, red (R); and the third color, blue (B).

In the present embodiment, the first to third photoelectric conversion portions 31 to 33 may be formed by employing any of the following methods: photodiodes are formed in the semiconductor substrate 12 by forming p-type semiconductor regions and n-type semiconductor regions; and photoelectric conversion films are formed over the semiconductor substrate 12. The first to third photoelectric conversion portions 31 to 33 may be formed by respectively using photodiodes or photoelectric conversion films, or by combining the photodiodes and the photoelectric conversion films.

The method by which the first to third photoelectric conversion portions 31 to 33 are formed by forming three layers of photodiodes in a semiconductor substrate is disclosed in JP 2009-516914A described above, for example.

The method by which the first to third photoelectric conversion portions 31 to 33 are formed by forming three layers of photoelectric conversion films on a semiconductor substrate is disclosed in JP 2011-146635A, for example.

The method by which the first to third photoelectric conversion portions 31 to 33 are formed by combining an electric conversion film formed on a semiconductor substrate and photodiodes in the semiconductor substrate is disclosed in JP 2011-29337A, for example.

### Circuit Configuration of Pixel 2

FIG. 3 shows a circuit configuration example of each pixel 2.

The pixel 2 includes the first to third photoelectric conversion portions 31 to 33, transfer transistors Tr1, Tr2, and Tr3, a floating diffusion region FD, a reset transistor Tr4, an amplification transistor Tr5, and a select transistor Tr6.

When being turned on due to a TRG (G) signal supplied to a gate electrode of the transfer transistor Tr1, the transfer transistor Tr1 transfers a charge accumulated in the first photoelectric conversion portion 31 to the floating diffusion region FD, the charge corresponding to an amount of received green color light. Similarly, when being turned on due to a TRG (R) signal supplied to a gate electrode of the transfer transistor Tr2, the transfer transistor Tr2 transfers a charge accumulated in the second photoelectric conversion portion 32 to the floating diffusion region FD, the charge corresponding to an amount of received red color light. When being turned on due to a TRG (B) signal supplied to a gate electrode of the transfer transistor Tr3, the transfer transistor Tr3 transfers a charge accumulated in the third photoelectric conversion portion 33 to the floating diffusion region FD, the charge corresponding to an amount of received blue color light.

When being turned on due to an RST signal supplied to a gate electrode of the reset transistor Tr4, the reset transistor Tr4 is turned on and thereby resets the floating diffusion region FD (discharges the charges from the floating diffusion region FD).

The amplification transistor Tr5 amplifies pixel signals from the floating diffusion region FD and outputs the pixel signals to the select transistor Tr6. When being turned on due to a SEL signal supplied to a gate electrode of the select transistor Tr6, the select transistor Tr6 outputs the pixel signals from the amplification transistor Tr5 to the corresponding column signal processing circuit 5.

The solid-state imaging device 1 having the aforementioned configuration has output mode of all-pixel output mode and thinning mode. In the all-pixel output mode, the pixels 2 of the pixel region 3 output respective pixel signal. In the thinning mode, pixel signals are outputted at lower resolution than the resolution in the all-pixel output mode and at high frame rate, the lower resolution being based on a smaller number of the pixels 2 in the pixel region 3 than the total number thereof The all-pixel output mode is used in a case where resolution is regarded as important, for example, in a case where a still image is captured. The thinning mode is used in a case where a frame rate is regarded as important, for example, in a case where a moving image is taken.

### Explanation of All-Pixel Output Mode

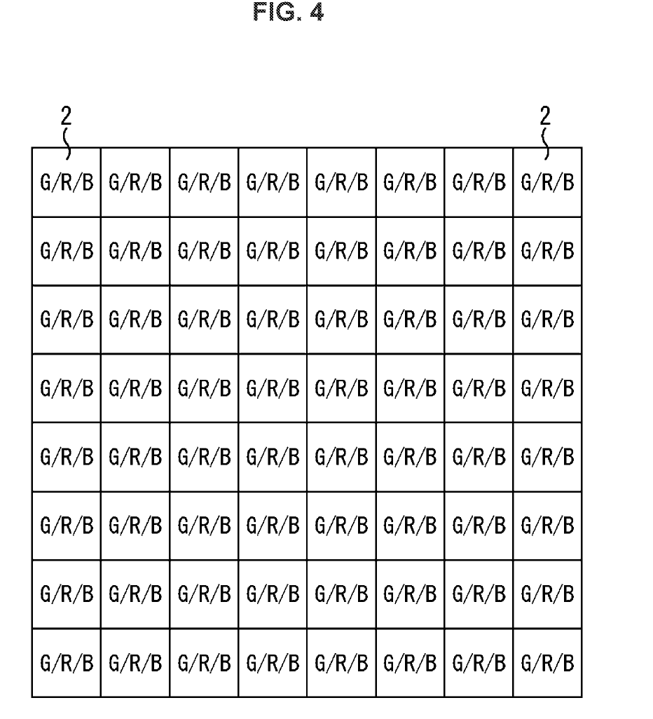

FIG. 4 is a diagram illustrating output signals of the pixels 2 in the case where the output mode is the all-pixel output mode.

FIG. 4 shows the pixels 2 in the pixel region 3 (FIG. 1) which are a total of 64 pixels, eight pixels in each of horizontal and vertical directions (8×8).

In FIG. 4, “G/R/B” shown in each pixel 2 means that the pixel 2 outputs a G signal which is a green pixel signal photoelectrically converted by the first photoelectric conversion portion 31, an R signal which is a red pixel signal photoelectrically converted by the second photoelectric conversion portion 32, and a B signal which is a blue pixel signal photoelectrically converted by the third photoelectric conversion portion 33.

Accordingly, when the output mode is the all-pixel output mode, the solid-state imaging device 1 outputs the pixel signals of the three colors of R, G, and B (the R signal, the G signal, and the B signal) from each pixel 2.

### Explanation of Thinning Mode

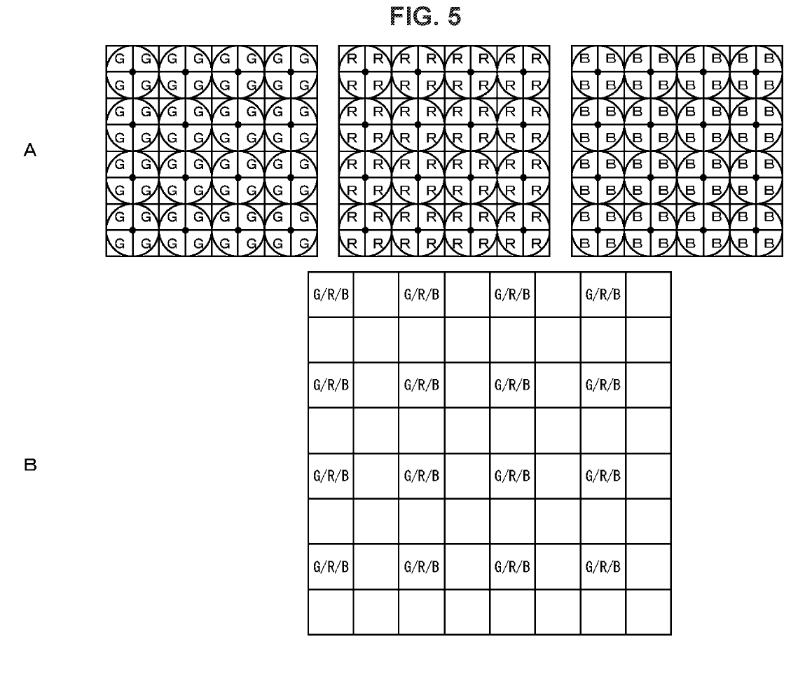

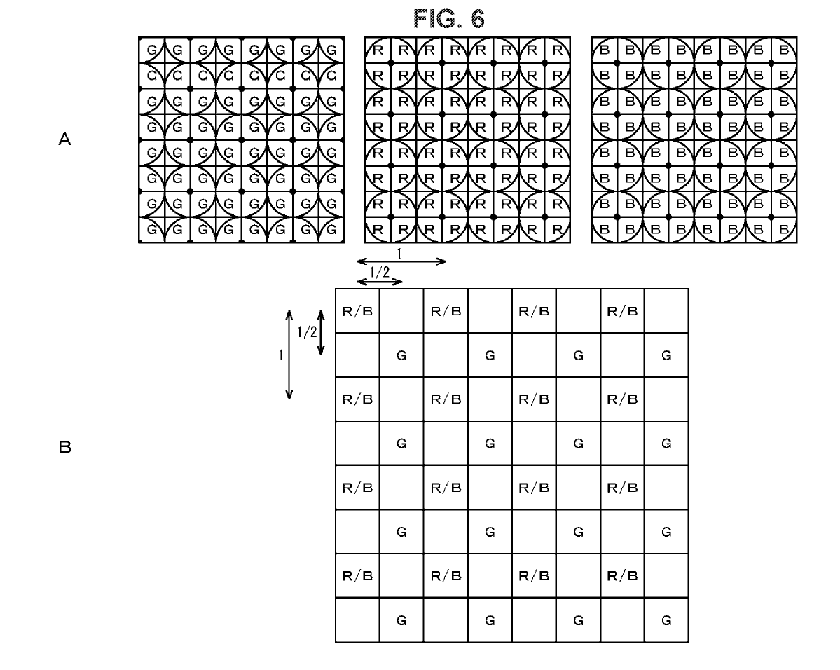

Next, output signals of pixels 2 in the case where the output mode is the thinning mode will be described with reference to FIGS. 5 and 6.

When the output mode is the thinning mode, the solid-state imaging device 1 adds up pixel signals of pixels adjacent to one another, and outputs the addition result as a pixel signal of one pixel.

FIG. 5 shows an example of general addition processing in the case where pixel signals of four adjacent pixels are added up, and the addition result is outputted as a pixel signal of one pixel.

FIG. 5A shows groups of pixels 2 to be added up, for each of color components of R, G, and B. Each circle including four pixels, i.e., 2×2 pixels in

FIG. 5A represents an addition region, from which a pixel signal is outputted as a pixel signal of one pixel.

Black dots in the centers of the circles in FIG. 5A represent output positions of pixel signals of each color component (hereinafter, also referred to as color signals) in the case where pixel signals of the four pixels, i.e., the 2×2 pixels are added up and the result is outputted as a pixel signal of one signal. Each of the output positions of the color signal corresponds to the gravity center of the color signals of the plurality of pixels in the addition region.

FIG. 5B is a diagram showing a positional relationship of the output positions of the color signals.

As shown in FIG. 5B, in the general addition processing, the same region is set as the addition region for the color components of R, G, and B, and the color signals of the color components of R, G, and B are outputted at the same position (pixel).

In contrast, FIG. 6 shows an example of addition processing performed by the solid-state imaging device 1 when the output mode is the thinning mode.

FIG. 6A shows addition regions used in the addition processing by the solid-state imaging device 1, for each of the color components of R, G, and B, like FIG. 5A. FIG. 6B shows output positions of the color signals, like FIG. 5B.

As shown in FIG. 6A, the solid-state imaging device 1 sets the addition regions of the G color component and the addition regions of the R and B color components as regions shifted from one another at regular intervals. Thereby, as shown in FIG. 6B, the G color signal output positions are shifted from the R and B color signal output positions at the regular intervals. The shift distance between the G color signal output position and the R and B color signal output position is ½ of an interval between the R or B color signal output positions.

When the R, G, and B color signals obtained by setting the addition regions in this way are converted into luminance signals, each luminance signal is obtained at each output position of the R, G, and B color signals. As described above, the color signals of each color are added up in such a manner that the G signal output position is shifted from the R and B signal output position by ½ of the interval between the R and B signal output positions, and the addition result is outputted. This leads to frequent spatial sampling for an outputted image. Thus, the output resolution can be enhanced in comparison with the general addition processing shown in FIG. 5.

### Circuit Operation in All-Pixel Output Mode

Next, a description is given of drive control over the pixels 2 in each output mode.

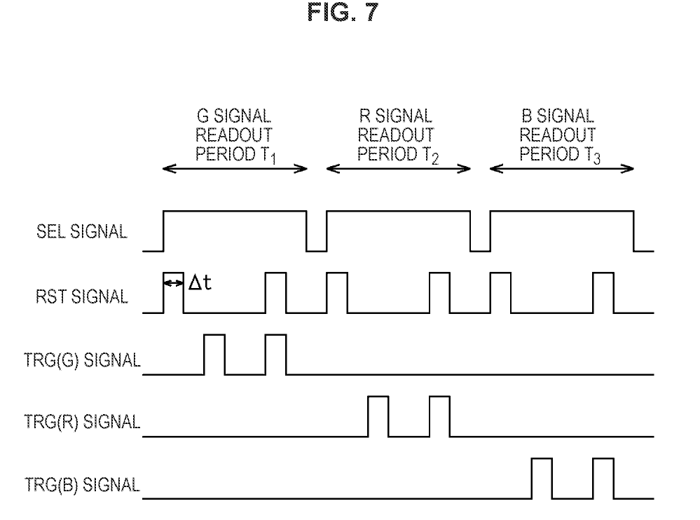

FIG. 7 shows a timing chart of an operation of each pixel 2 in the case where the output mode is the all-pixel output mode.

In one of the pixels 2 which is a target of reading out pixel signals, a G signal readout period T₁ for reading out a G signal, an R signal readout period T₂ for reading out an R signal, and a B readout period T₃ for reading out a B signal are set in order.

In the G signal readout period T₁, a SEL signal which is a control signal of the select transistor Tr6 is set to be kept Hi in the G signal readout period T₁ to thereby turn on the select transistor Tr6. Then, an RST signal which is a control signal of the reset transistor Tr4 is kept Hi in a At period at the beginning of the G signal readout period T₁. Thereby, the reset transistor Tr4 is turned on, and the floating diffusion region FD is reset.

After the reset transistor Tr4 is turned off, a TRG (G) signal which is a control signal of the transfer transistor Tr1 is set to be Hi in the At period to thereby turn on the transfer transistor Tr1. When the transfer transistor Tr1 is turned on, a charge (G signal) accumulated in the first photoelectric conversion portion 31 is transferred to the floating diffusion region FD, the charge corresponding to an amount of received green color (G) light. The G signal transferred to the floating diffusion region FD is amplified by the amplification transistor TrS, and then is outputted to the corresponding column signal processing circuit 5 through the select transistor Tr6.

After a predetermine time period passes after the transfer transistor Tr1 is turned off, the RST signal and the TRG (G) signal are again set to be Hi to thereby reset the charge in the first photoelectric conversion portion 31.

The operation in the steps described so far is executed in the G signal readout period T₁.

Also in the R signal readout period T₂ and in the B signal readout period T₃ after the G signal readout period T₁, the same operation as in the G signal readout period T₁ is executed instead of the transfer transistor Tr1 in the G signal readout period T₁ described above, except that the transfer transistors Tr2 and Tr3 are controlled in the R and B signal readout periods T₂ and T₃, respectively.

### Circuit operation in Thinning Mode

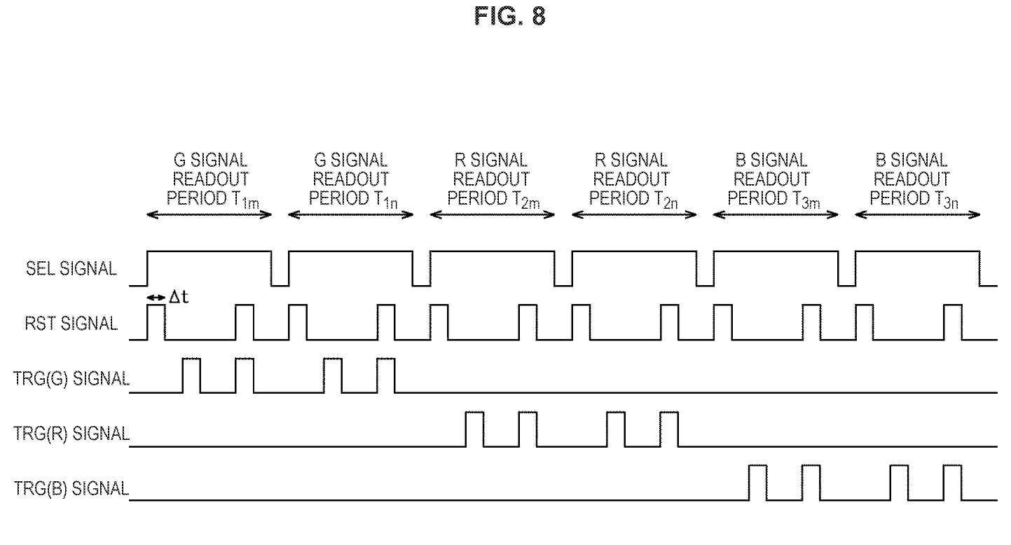

Next, with reference to FIG. 8, a description is given of an operation of the pixels 2 in the case where the output mode is the thinning mode and thus pixel signals of four adjacent pixels 2 are added up and the result is outputted.

FIG. 8 shows a timing chart of an operation of the pixels 2 in the addition regions in certain two rows, the addition regions being shown in the circles in FIG. 6A.

When the solid-state imaging device 1 adds up pixel signals of four adjacent pixels 2 and outputs the result, the vertical drive circuit 4 performs readout control in units of two rows of the addition regions. Here, an upper row of each two-row unit of the addition regions in the pixel region 3 is referred to as a row m, and a lower row thereof is referred to as a row n.

The vertical drive circuit 4 sets, in order, a G signal readout period T₁ₘ, a G signal readout period T₁ₙ, an R signal readout period T₂ₘ, an R signal readout period T₂ₙ, a B signal readout period T₃ₘ, and a B signal readout period T₃ₙ.

Firstly, in the G signal readout period T₁ₘ, the vertical drive circuit 4 reads out a G signal of each pixel 2 in the upper row m in the two-row unit under the same control as in the G signal readout period T₁ described with reference to FIG. 7. Next, in the G signal readout period T₁ₙ, the vertical drive circuit 4 reads out a G signal of each pixel 2 in the lower row n of the two-row unit under the same control as in the G signal readout period T₁ described with reference to FIG. 7.

In the same manner, the vertical drive circuit 4 reads out: an R signal of each pixel 2 in the upper row m of the two-row unit in the R signal readout period T₂ₘ; and an R signal of each pixel 2 in the lower row n of the two-row unit in the R signal readout period T₂ₙ. Next, the vertical drive circuit 4 reads out: a B signal of each pixel 2 in the upper row m of the two-row unit in the B signal readout period T₃ₘ; and a B signal of each pixel 2 in the lower row n of the two-row unit in the B signal readout period T₃ₙ.

As seen with reference to FIG. 6A, the row m for the G signal does not correspond to the rows m for the R and B signals, and the row n for the G signal corresponds to the rows m for the R and B signals.

By controlling the driving of the pixels 2 in this way, the pixel signals of the two rows of the rows m and n for each color component of R, G, and B are supplied to the column signal processing circuits 5 arranged for the respective columns of the pixels 2.

Note that although the examples of reading out the G signal, the R signal, and the B signal in this order have been described with reference to FIGS. 7 and 8, the order of reading out the color signals is not limited to the order in the aforementioned examples, and may be set to be any order.

### Explanation of Pixel-Addition/Output Processing

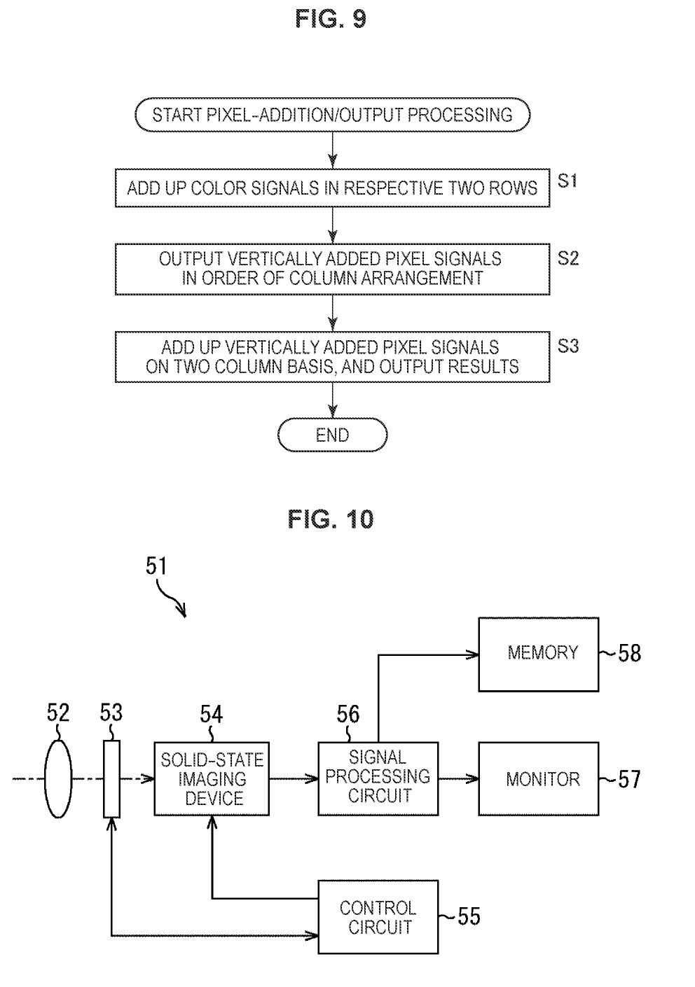

Next, pixel-addition/output processing will be described with reference to a flowchart in FIG. 9. In the pixel-addition/output processing, color signals in two rows supplied to the column signal processing circuits 5, and color signals of four pixels, i.e., the 2×2 pixels are added up to output the result as color signals of one pixel.

Firstly, in Step 51, each of the column signal processing circuits 5 adds color signals in the respective rows m and n. Thereby, a vertically added pixel signal is obtained which results from the addition of the color signals of the two pixels arranged in a vertical direction.

In Step S2, the column signal processing circuits 5 output the respective vertically added pixel signals to the output circuit 7 in order of column arrangement.

In Step S3, the output circuit 7 adds up two of the vertically added pixel signals every two adjacent columns, the vertically added pixel signals being supplied in order from the column signal processing circuits 5 of the respective columns. Thereby, horizontally and vertically added pixel signals are obtained also in color signals in a horizontal direction, the horizontally and vertically added pixel signals each resulting from the addition of color signals of two pixels arranged in the horizontal direction. That is, each of the horizontally and vertically added pixel signals is a signal representing the four pixels, i.e., 2×2 pixels encircled in FIG. 6A. Then, the output circuit 7 outputs the horizontally and vertically added pixel signals resulting from the addition in order of the addition.

The processing in Steps 51 to S are executed for each of R, G, and B color signals in predetermined order or in parallel.

In the aforementioned example, each column signal processing circuit 5 adds up the color signals of the two pixels in the vertical direction, and the output circuit 7 adds up the color signals of the two pixels in the horizontal direction. However, any section may perform the addition processing of the color signals in the vertical direction and the horizontal direction. For example, adjacent column signal processing circuits 5 may perform the addition in the horizontal direction, and then output horizontally and vertically added pixel signals to the output circuit 7. Alternatively, the output circuit 7 may perform the addition processing of the color signals of the pixels in both the vertical direction and the horizontal direction. Still alternatively, a block for the addition of the color signals of the pixels in the vertical and horizontal directions may be additionally provided, for example.

In the aforementioned embodiment, the example has been described in which the pixel signals (color signals) of the four pixels, i.e., 2×2 pixels are added up and the addition result is outputted as a pixel signal (color signal) of one pixel. However, the number of added pixels in the horizontal and vertical directions may be set (changed) to be any number such as nine, i.e., 3×3 or 16, i.e., 4×4.

In addition, in the aforementioned embodiment, the G signal output positions are shifted from the R and B signal output positions by ½ of the interval between the R and B signal output positions. However, the shift distance is not limited to ½ of the interval between the R and B signal output positions, and may be any predetermined distance. To put it differently, the G signal output positions may be shifted from the R and B signal output positions at any regular intervals.

For example, in a case where color signals of nine pixels, i.e., 3×3 pixels are added up and the result is outputted, simply adding the color signals leads to output of the color signals at the G signal output position shifted from the R and B signal output position by ⅓ of the interval between the R and B signal output positions. The addition result may be outputted at the positions shifted by ⅓ in this way, or may be outputted at positions shifted, for example, by ½ of the interval in the following way. Specifically, in the addition processing of three pixels in the horizontal direction (lengthwise), the weightings (ratio) of the color signals of a left pixel, a center pixel, and a right pixel is converted into 1:1:2.

Moreover, in the aforementioned embodiment, the color signal whose output positions are shifted is the G signal among the three color signals, but any of the other color signals may have shifted output positions. Further, the colors to be separated are the three colors of R, G, and B, but may be two colors or four colors or more. The colors may also be other than R, G, and B, for example, magenta (Mg), cyan (Cy), and yellow (Ye).

In conclusion, the pixel-addition/output processing in the thinning mode to which the embodiment of the present technology is applied may be processing performed in the following manner. In the solid-state imaging device 1 including the pixels 2 which are regularly arranged in the two-dimensional array form and each of which has the pixel structure of separating colors in the substrate depth direction, addition is performed when pixel signals of the plurality of pixels 2 are added up to be outputted, by setting addition regions of pixel signals (color signals) of a first color component to be shifted from addition regions of pixel signals (color signals) of a second color component at regular intervals.

### Example of Application to Electronic Apparatus

The aforementioned solid-state imaging device 1 is applicable to various electronic apparatuses, for example, an imaging apparatus such as a digital still camera or a digital video camera, a mobile phone having an imaging function, and another apparatus having an imaging function.

FIG. 10 is a block diagram showing a configuration example of an imaging apparatus serving as an electronic apparatus to which the embodiment of the present technology is applied.

An imaging apparatus 51 shown in FIG. 10 includes an optical element 52, a shutter device 53, a solid-state imaging device 54, a control circuit 55, a signal processing circuit 56, a monitor 57, and a memory 58, and is capable of capturing still images and moving images.

The optical element 52 includes one or a plurality of lenses, and guides light (incident light) from a subject to the solid-state imaging device 54 to form an image on a light receiving surface of the solid-state imaging device 54.

The shutter device 53 is arranged between the optical element 52 and the solid-state imaging device 54, and controls a light emitting period and a light-shielding period for the solid-state imaging device 54 in accordance with control by the control circuit 55.

The solid-state imaging device 54 is formed by the aforementioned solid-state imaging device 1. The solid-state imaging device 54 accumulates signal charges for a predetermined period in accordance with light passing through the optical element 52 and the shutter device 53 to form an image on the light receiving surface. The signal charges accumulated in the solid-state imaging device 54 are transferred according to drive signals (timing signals) supplied from the control circuit 55. The solid-state imaging device 54 may be configured as one chip by itself or may be configured as part of a camera module packaged together with the optical element 52, the signal processing circuit 56, and the like.

The control circuit 55 outputs drive signals for controlling a transfer operation of the solid-state imaging device 54 and a shutter operation of the shutter device 53, and thereby drives the solid-state imaging device 54 and the shutter device 53.

The signal processing circuit 56 performs various signal processing on the signal charges outputted from the solid-state imaging device 54. An image (image data) obtained by the signal processing performed by the signal processing circuit 56 is supplied to the monitor 57 to be displayed thereon, or supplied to the memory 58 to be stored (recorded) therein.

The embodiment of the present technology is not limited to the aforementioned embodiment. It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1)
A solid-state imaging device including a plurality of pixels which are arranged in a two-dimensional array form and in each of which color separation is performed in a substrate depth direction, the solid-state imaging device including:
   a pixel addition section which performs addition, when pixel signals of the plurality of pixels are added up to be outputted, by setting addition regions of pixel signals of a first color component to be shifted from addition regions of pixel signals of a second color component at regular intervals.
      (2)
The solid-state imaging device according to (1),
   wherein the pixel addition section adds up the pixel signals of the plurality of pixels in each of the addition regions in such a manner that gravity centers of the second color component are shifted from gravity centers of the first color component by ½ of an interval between the gravity centers of the first color component.
      (3)
The solid-state imaging device according to (1) or (2),
   wherein the first color component is red or blue, and the second color component is green.
      (4)
The solid-state imaging device according to any one of (1) to (3),
   wherein each of the pixels includes, in a semiconductor substrate,
      a plurality of photoelectric conversion regions for performing color separation between the first color component and the second color component.
         (5)
The solid-state imaging device according to any one of (1) to (3),
   wherein each of the pixels includes, over a semiconductor substrate,
      a plurality of photoelectric conversion films for performing color separation between the first color component and the second color component.
         (6)
The solid-state imaging device according to any one of (1) to (3),
   wherein each of the pixels includes:
      a photoelectric conversion film over a semiconductor substrate; and
      a photoelectric conversion region in the semiconductor substrate,
      wherein the photoelectric conversion film performs color separation of the first color component, and the photoelectric conversion region performs color separation of the second color component.
         (7)
A method for controlling a solid-state imaging device including a plurality of pixels which are arranged in a two-dimensional array form and in each of which color separation is performed in a substrate depth direction, the method being performed by the solid-state imaging device, the method including:
   performing addition, when pixel signals of the plurality of pixels are added up to be outputted, by setting addition regions of pixel signals of a first color component to be shifted from addition regions of pixel signals of a second color component at regular intervals.
      (8)
An electronic apparatus including:
   a solid-state imaging device including a plurality of pixels which are arranged in a two-dimensional array form and in each of which color separation is performed in a substrate depth direction, the solid-state imaging device including
   a pixel addition section which performs addition, when pixel signals of the plurality of pixels are added up to be outputted, by setting addition regions of pixel signals of a first color component to be shifted from addition regions of pixel signals of a second color component at regular intervals.

The present disclosure contains subject matter related to that disclosed in Japanese Priority Patent Application JP 2012-141670 filed in the Japan Patent Office on Jun. 25, 2012, the entire content of which is hereby incorporated by reference.

What is claimed is:

1. A solid-state imaging device including a plurality of pixels which are arranged in a two-dimensional array form and in each of which color separation is performed in a substrate depth direction, the solid-state imaging device comprising:
a pixel addition section which performs addition, when pixel signals of the plurality of pixels are added up to be outputted, by setting addition regions of pixel signals of a first color component to be shifted from addition regions of pixel signals of a second color component at regular intervals.

2. The solid-state imaging device according to claim 1,
wherein the pixel addition section adds up the pixel signals of the plurality of pixels in each of the addition regions in such a manner that gravity centers of the second color component are shifted from gravity centers of the first color component by ½ of an interval between the gravity centers of the first color component.

3. The solid-state imaging device according to claim 1,
wherein the first color component is red or blue, and the second color component is green.

4. The solid-state imaging device according to claim 1,
wherein each of the pixels includes, in a semiconductor substrate,
a plurality of photoelectric conversion regions for performing color separation between the first color component and the second color component.

5. The solid-state imaging device according to claim 1,
wherein each of the pixels includes, over a semiconductor substrate,
a plurality of photoelectric conversion films for performing color separation between the first color component and the second color component.

6. The solid-state imaging device according to claim 1,
wherein each of the pixels includes:
a photoelectric conversion film over a semiconductor substrate; and
a photoelectric conversion region in the semiconductor substrate,
wherein the photoelectric conversion film performs color separation of the first color component, and the photoelectric conversion region performs color separation of the second color component.

7. A method for controlling a solid-state imaging device including a plurality of pixels which are arranged in a two-dimensional array form and in each of which color separation is performed in a substrate depth direction, the method being performed by the solid-state imaging device, the method comprising:
performing addition, when pixel signals of the plurality of pixels are added up to be outputted, by setting addition regions of pixel signals of a first color component to be shifted from addition regions of pixel signals of a second color component at regular intervals.

8. An electronic apparatus comprising:
a solid-state imaging device including a plurality of pixels which are arranged in a two-dimensional array form and in each of which color separation is performed in a substrate depth direction, the solid-state imaging device including
a pixel addition section which performs addition, when pixel signals of the plurality of pixels are added up to be outputted, by setting addition regions of pixel signals of a first color component to be shifted from addition regions of pixel signals of a second color component at regular intervals.
